(19) United States
(12) Patent Application Publication
(10) Pub. No.: US 2025/0218843 A1
(43) Pub. Date: Jul. 3, 2025

(54) SUBSTRATE HOLDING UNIT AND SUBSTRATE PROCESSING APPARATUS

(71) Applicant: SAMSUNG ELECTRONICS CO., LTD., Suwon-si (KR)

(72) Inventors: Iksu BYUN, Suwon-si (KR); Yongtae KIM, Suwon-si (KR); Songyun KANG, Suwon-si (KR); Kyungrim KIM, Suwon-si (KR); Junrae KIM, Suwon-si (KR)

(73) Assignee: SAMSUNG ELECTRONICS CO., LTD., Suwon-si (KR)

(21) Appl. No.: 18/736,317

(22) Filed: Jun. 6, 2024

(30) Foreign Application Priority Data
Dec. 28, 2023 (KR) 10-2023-0194191

(51) Int. Cl. H01L 21/683; H01J 37/32

(52) U.S. Cl. CPC H01L 21/6833; H01J 37/32568; H01J 37/32724; H01J 2237/2007; H01J 2237/3321

(57) ABSTRACT

A substrate holder includes: a core body having a first surface facing a direction in which a substrate is mounted and a second surface opposite to the first surface; an electrode layer on the first surface and the second surface of the core body; a ceramic insulating layer covering the electrode layer on the first surface and the second surface of the core body; a coating layer covering the ceramic insulating layer and forming an outermost surface facing the substrate; and a buffer layer between the ceramic insulating layer and the coating layer, wherein the buffer layer includes a material having a strain energy density lower than a strain energy density of the coating layer.

### CROSS-REFERENCE TO RELATED APPLICATION

This application is based on and claims priority under 35 U.S.C. § 119 of Korean Patent Application No. 10-2023-0194191, filed on Dec. 28, 2023, in the Korean Intellectual Property Office, the disclosure of which is incorporated by reference herein in its entirety.

### BACKGROUND

The disclosure relates to a substrate holder and a substrate processing apparatus.

Semiconductor device manufacturing processes include various deposition processes such as etching processes and chemical vapor deposition (CVD) on semiconductor wafers. Substrate processing apparatuses for these processes may include, for example, deposition devices (such as CVD devices or sputtering devices) and etching devices (such as plasma etching devices).

The substrate processing apparatuses may include heating devices for heating semiconductor wafers to a high temperature. In some substrate processing apparatuses, the heating device may be used in combination with a substrate holder (for example, a susceptor).

### SUMMARY

Provided is a substrate holder combined with a heater in which problems due to internal stress are prevented. Provided is a substrate processing apparatus having a substrate holder in which problems due to internal stress are prevented.

According to an aspect of the disclosure, a substrate holder includes: a core body having a first surface facing a direction in which a substrate is mounted and a second surface opposite to the first surface; an electrode layer on the first surface and the second surface of the core body; a ceramic insulating layer covering the electrode layer on the first surface and the second surface of the core body; a coating layer covering the ceramic insulating layer and forming an outermost surface facing the substrate; and a buffer layer between the ceramic insulating layer and the coating layer, wherein the buffer layer includes a material having a strain energy density lower than a strain energy density of the coating layer.

According to an aspect of the disclosure, a substrate holder includes: a core body having a first surface facing a direction in which a substrate is mounted and a second surface opposite to the first surface; an electrode layer on the core body, the electrode layer including pyrolytic graphite configured to provide heat to the substrate; a ceramic insulating layer covering the electrode layer, the ceramic insulating layer being located on the first surface and the second surface of the core body, and the ceramic insulating layer including pyrolytic boron nitride; a coating layer covering the ceramic insulating layer, the coating layer being configured to provide an outermost surface facing the substrate, and the coating layer including at least one of a lanthanum oxide series, a metal oxide, a metal nitride, and a metal carbide, wherein stiffness of the coating layer is higher than stiffness of the pyrolytic boron nitride; and a buffer layer between the ceramic insulating layer and the coating layer, the buffer layer including at least one of silicon nitride (Si₃N₄), yttrium silicate (Γ-Y₂Si₂O₇), aluminum nitride (AlN), α-silicon carbide (α-SiC), tungsten carbide (WC), β-silicon carbide (β-SiC), boron carbide (B₄C) and zirconium carbide (ZrC).

According to an aspect of the disclosure, A substrate processing apparatus includes: a process chamber having an internal space for processing a substrate; a first support in the internal space and supporting the substrate; and a gas supplier configured to supply process gas to the internal space, wherein the first support includes: a core body having a first surface facing a direction in which the substrate is mounted and a second surface opposite to the first surface; an electrode layer on the first surface and the second surface of the core body; a ceramic insulating layer covering the electrode layer on the first surface and the second surface of the core body; a coating layer covering the ceramic insulating layer and being an outermost surface facing the substrate; a buffer layer between the ceramic insulating layer and the coating layer, the buffer layer including a material having a strain energy density lower than a strain energy density of the coating layer; a plate facing the second surface of the core body; a second support connected to the plate; and a power supply line connected to the electrode layer through an inside of the second support.

### BRIEF DESCRIPTION OF DRAWINGS

The above and other aspects, features, and advantages of the disclosure will be more clearly understood from the following detailed description, taken in conjunction with the accompanying drawings, in which:

FIG. 1 is a schematic cross-sectional view illustrating a substrate processing apparatus according to example embodiments;

FIG. 2 is a plan view illustrating a substrate holder (or a substrate heater) employable in the substrate processing apparatus illustrated in FIG. 1;

FIG. 3 is a cross-sectional view illustrating a substrate holder employable in the substrate processing apparatus illustrated in FIG. 2;

FIG. 4 is a partially enlarged view illustrating area “A” in the substrate holder of FIG. 3;

FIGS. 5A to 5C and 6A to 6C are graphs illustrating characteristics of a buffer layer applicable to a substrate holder;

FIGS. 7 to 10 are cross-sectional views respectively illustrating a substrate holder according to various embodiments; and

FIGS. 11A to 11G are cross-sectional views illustrating a method of manufacturing a substrate holder according to example embodiments.

### DETAILED DESCRIPTION

Hereinafter, example embodiments will be described with reference to the accompanying drawings. The description merely illustrates the principles of the disclosure. Those skilled in the art will be able to devise one or more arrangements that, although not explicitly described herein, embody the principles of the disclosure. Furthermore, all examples recited herein are principally intended expressly to be only for explanatory purposes to help the reader in understanding the principles of the disclosure and the concepts contributed by the inventor to furthering the art and are to be construed as being without limitation to such specifically recited examples and conditions. Moreover, all statements herein reciting principles, aspects, and embodiments of the disclosure, as well as specific examples thereof, are intended to encompass equivalents thereof.

Terms used in the disclosure are used only to describe a specific embodiment, and may not be intended to limit the scope of another embodiment. A singular expression may include a plural expression unless it is clearly meant differently in the context. The terms used herein, including a technical or scientific term, may have the same meaning as generally understood by a person having ordinary knowledge in the technical field described in the present disclosure. Terms defined in a general dictionary among the terms used in the present disclosure may be interpreted with the same or similar meaning as a contextual meaning of related technology, and unless clearly defined in the present disclosure, it is not interpreted in an ideal or excessively formal meaning. In some cases, even terms defined in the disclosure cannot be interpreted to exclude embodiments of the present disclosure.

In one or more embodiments of the disclosure described below, a hardware approach is described as an example. However, since the one or more embodiments of the disclosure include technology that uses both hardware and software, the various embodiments of the present disclosure do not exclude a software-based approach.

In addition, in the disclosure, in order to determine whether a specific condition is satisfied or fulfilled, an expression of more than or less than may be used, but this is only a description for expressing an example, and does not exclude description of more than or equal to or less than or equal to. A condition described as ‘more than or equal to’ may be replaced with ‘more than’, a condition described as ‘less than or equal to’ may be replaced with ‘less than’, and a condition described as ‘more than or equal to and less than’ may be replaced with ‘more than and less than or equal to’.

The terms “include” and “comprise”, and the derivatives thereof refer to inclusion without limitation. The term “or” is an inclusive term meaning “and/or”. The phrase “associated with,” as well as derivatives thereof, refer to include, be included within, interconnect with, contain, be contained within, connect to or with, couple to or with, be communicable with, cooperate with, interleave, juxtapose, be proximate to, be bound to or with, have, have a property of, have a relationship to or with, or the like. The phrase “at least one of,” when used with a list of items, means that different combinations of one or more of the listed items may be used, and only one item in the list may be needed. For example, “at least one of A, B, and C” includes any of the following combinations: A, B, C, A and B, A and C, B and C, and A and B and C, and any variations thereof. As an additional example, the expression “at least one of a, b, or c” may indicate only a, only b, only c, both a and b, both a and c, both b and c, all of a, b, and c, or variations thereof. Similarly, the term “set” means one or more. Accordingly, the set of items may be a single item or a collection of two or more items.

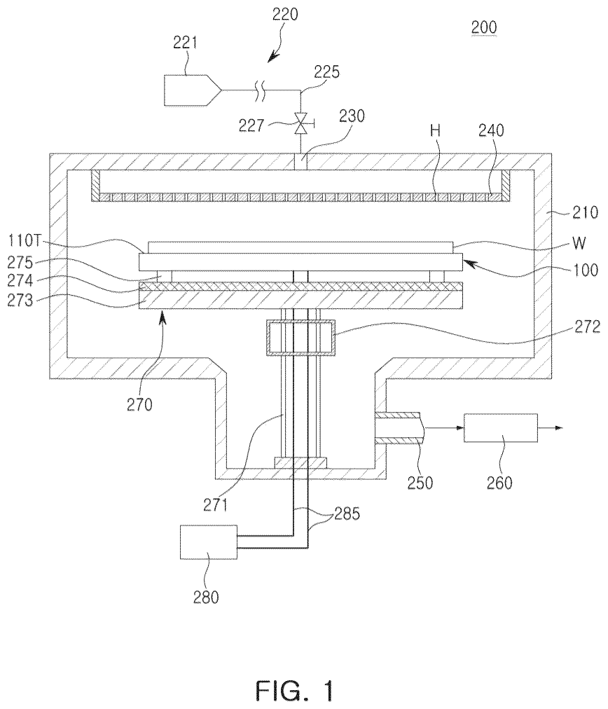

FIG. 1 is a schematic cross-sectional view illustrating a substrate processing apparatus according to example embodiments. Referring to FIG. 1, a substrate processing apparatus 200 according to this embodiment includes a process chamber 201 having an internal space IS for processing a substrate (W), a substrate holder 100 disposed in the internal space IS, and a gas supplier 220 for supplying gas to the internal space IS.

The substrate processing apparatus 200 according to this embodiment is illustrated as a ‘plasma enhanced chemical vapor deposition’ (PECVD) apparatus that deposits a required film on the substrate W disposed on the substrate holder 100 using plasma. The substrate processing apparatus 200 according to this embodiment is not limited thereto, and may be implemented as various other devices for performing processes necessary for semiconductor manufacturing while the substrate W is heated to a high temperature.

The process chamber 210 may have an internal space IS for performing the process, and may have a gas inlet port 230 for introducing gas, and an exhaust port 250 for exhausting reaction by-products and residual gas generated during the process in one side (for example, upper end) of the process chamber 210.

Referring to FIG. 1, the gas supplier 220 supplies process gas to the internal space IS through the gas inlet port 230. The gas supplier 220 may include a gas storage 221, a gas supply line 225, and a valve. The gas supply line 225 connects the gas storage 221 and the gas inlet port 230, and the process gas stored in the gas storage 221 may be supplied through the gas supply line 225 and the gas inlet port 230. The valve is installed in the gas supply line 225 and may open and close the gas supply passage or adjust the flow rate of the process gas supplied to the internal space IS.

The process gas supplied through the gas inlet port 230 may be sprayed onto the substrate W through the shower head 240. The shower head 240 has spray holes H for spraying gas, and may spray the reaction gas uniformly on the substrate W through the spray holes H. The shower head 240 may be disposed on the upper side of the internal space IS of the process chamber 210 to face the substrate holder 100. The shower head 240 may have a diameter larger than the diameter of the substrate holder 100.

The substrate holder 100 may include a support 271 extending upwardly from the bottom of the process chamber 210, and a plate 270 connected to the support 271 to support the substrate holder 100. The substrate holder 100 may be fastened to the plate 270 in a attachable and detachable state.

The plate 270 is a cooler, and may have a heat shield layer 274 on the upper surface of the cooling plate 273, to prevent heat generated from the upper substrate holder 100 from being transferred to the chamber. Accordingly, the heat shield layer 274 may include a material with a very low heat transfer rate. The plate 270 may further include an angle controller 272 to tilt the upper surface at a predetermined angle with respect to the support 271, and the angle controller 272 may be a mechanical device capable of changing the angle between the support 271 and the plate 270 through a gear or the like. A fixing portion 275 (capable of fixing the substrate holder 100) may be disposed on the upper surface of the plate 270. The substrate holder 100 is physically coupled to the plate 270 by the fixing portion 275 and may be moved together.

The first and second power supply lines 285 connected to the substrate holder 100 may be connected to the electrodes of the substrate holder 100, and may be connected to a heating power source 280 located outside the process chamber 210 through the plate 270 and the support 271. In some embodiments, the support 271 has a hollow cylindrical structure, and the first and second power supply lines 285 may be disposed in the inner space of the support 271.

The substrate holder 100 is configured to support the substrate W to be processed in the internal space IS. The substrate holder 100 employed in this embodiment is coupled with a heating power source 280 that heats the substrate W to a required process temperature while fixing the same.

The substrate holder 100 may include a core body 110, a first insulating layer 120 on the core body 110, an electrode layer 150 on the first insulating layer 120, a second insulating layer 130 covering the electrode layer 150, a buffer layer 140, and a coating layer 160. The upper surface of the coating layer 160 may be provided as a substrate stage to form the upper surface 100T of the substrate holder 100 on which the substrate W is mounted, and the lower surface of the coating layer 160 may form the lower surface 100B of the substrate holder 100 in contact with the heat shield layer 274.

The substrate holder 100 is an electrostatic chuck heater, and the core body 110 includes carbon or a carbon composite material, and has a similar thermal expansion rate to pyrolytic boron nitride (pBN) and may contain materials with excellent thermal shock resistance. As a carbon material, graphite or the like may be used.

The core body 110 may have an upper surface facing the direction in which the substrate W is mounted, and a rear surface facing the plate 270 opposite to the upper surface. The upper electrode 150a connected to the first and second power supply lines 285 at the exact center of the core by 110 may include an opening hole 111 in which a connection portion 151 extending to the lower surface is disposed.

A first insulating layer 120 may be disposed surrounding the core body 110. The first insulating layer 120 may include pBN whose thermal expansion coefficient is in a range similar to that of the core body 110.

PBN has an electrical resistivity of 10⁸ to 10¹³ Ω·cm. The first insulating layer 120 having such an electrical resistivity allows a weak current to flow to the substrate W, thereby significantly increasing the electrostatic force known as the “Johnsen-Rahbek” effect. In addition, pBN compactly manufactured by chemical vapor deposition (CVD) has an electrical resistivity of about 10¹⁵ Ω·cm at room temperature, but decreases to 10⁸ to 10¹² Ω·cm at temperatures of 800° C. or higher. Accordingly, good electrostatic chucking force may be successfully provided by the “Johnsen-Rahbek” effect. The first insulating layer 120 covers the core body 110 to have a thickness of 100 μm to 300 μm and may cover the entire opening hole 111.

An electrode layer 150 including upper electrodes 150a and lower electrodes 150b may be disposed on the upper and lower surfaces of the first insulating layer 120, respectively. The electrode layer 150 may be formed of pyrolytic graphite (PG). In more detail, for example, the PG electrode layer 150 with a thickness of about 50 μm may be patterned to form upper electrodes 150a on the upper surface and lower electrodes 150b on the lower surface.

The upper electrodes 150a disposed on the upper surface serve as chuck electrodes and carry current for fixing the substrate W, as an object. The lower electrodes 150b disposed on the lower surface are heater electrodes, and may generate heat according to the applied voltage and apply the heat to the substrate W, which is the object.

The second insulating layer 130 may be disposed to completely cover the electrode layer 150. The second insulating layer 130 may include the same material as the first insulating layer 120, and may specifically include pBN. As described above, pBN may significantly increase the electrostatic force and completely covers the first insulating layer 120 to have a thickness (d1) of 100 μm to 300 μm from the electrode layer 150, and may be placed by filling in the opening hole 111. The second insulating layer 130 may be formed to have flat upper and lower surfaces. However, when the second insulating layer 130 includes pBN and when the second insulating layer 130 is placed on the outermost surface due to the low stiffness of pBN, particles may be generated due to friction during the process and periodic replacement may be required.

To prevent this, a coating layer 160 may be disposed surrounding the second insulating layer 130. The upper surface of the coating layer 160 is provided as a plate 270 to form the upper surface 100T of the substrate holder 100 on which the substrate W is mounted, and the lower surface of the coating layer 160 may form the lower surface 100B of the substrate holder 100 in contact with the heat shield layer 274. Accordingly, the surface of the coating layer 160 may become the uppermost surface 100T of the substrate holder 100.

The coating layer 160 may include a material having higher stiffness than the second insulating layer 130. For example, the coating layer 160 may include at least one of a lanthanum oxide series, a metal oxide, a metal nitride, and a metal carbide. As an example, the coating layer 160 may include any one of yttrium oxide (Y₂O₃), aluminum oxide (Al₂O₃), zirconium oxide (ZrO₂), aluminum nitride (AlN), and silicon carbide (SiC). The coating layer 160 may meet a thickness (d2) between 1 μm and 1 mm. The coating layer 160 has a smaller coefficient of thermal expansion (CTE) than the second insulating layer 130, but has high stiffness, thereby protecting the lower second insulating layer 130. In detail, yttrium oxide (Y₂O₃) has higher stiffness than the second insulating layer 130 and has plasma resistance, and may, thus, extend the life of the substrate holder 100 during various heat treatments and plasma treatments in the chamber. This may delay the replacement period.

Protruding patterns 161 may be disposed on the surface of the coating layer 160. The protruding patterns 161 may have uniform sizes and be arranged irregularly, and by forming a space separated from the substrate W placed on top, a passage for heat and source gas may be formed. The protruding patterns 161 may be disposed limited to only the upper surface 100T of the coating layer 160 and may not be disposed on the lower surface 100B. Additionally, the protruding patterns 161 may not be disposed on the second insulating layer 130 and the buffer layer 140.

At least one layer of buffer layer 140 may be disposed between the coating layer 160 and the second insulating layer 130. The buffer layer 140 may disperse stress transmitted to the coating layer 160, and may include a material having a strain energy density that is smaller than the strain energy density of the coating layer 160. The strain energy density of the material forming the buffer layer 140 may have a smaller value than the strain energy density of pBN forming the second insulating layer 130. Accordingly, the buffer layer 140 may include a material having a strain energy density corresponding to that of pBN and the material forming the coating layer 160.

The buffer layer 140 may be a ceramic metal with high thermal stability, and for example, may include one of silicon nitride (Si₃N₄), yttrium silicate (Γ-Y₂Si₂O₇), aluminum nitride (AlN), α-silicon carbide (α-SiC), tungsten carbide (WC), β-silicon carbide (β-SiC), Boron carbide (B₄C), and zirconium carbide (ZrC). The buffer layer 140 may include a material having a lower strain energy density than the material of the coating layer 160, and since the strain energy density is proportional to [stiffness] and [thermal expansion coefficient (CTE) squared], the specific coefficient (Coeff.) to compare the strain energy density may be expressed as the product of the stiffness and the square of thermal expansion coefficient. Therefore, the optimal material may be applied by comparing the specific coefficients (Coeff.) of the coating layer 160 and the buffer layer 140. The buffer layer 140 may also be formed to meet a thickness (d3) between 1 μm and 1 mm.

Due to differences in mechanical properties (for example, stiffness, thermal expansion coefficient (CTE), etc.) between the second insulating layer 130 (pBN) and the coating layer 160, stress concentration occurring at the interface may be triggered due to temperature changes. Accordingly, cracks formed on the upper surface of the second insulating layer 130 due to the interface between the two layers and initial defects (holes and pits) generated during the process may extend to the upper surface of the coating layer 160 and become cracks.

By placing the buffer layer 140, which has a strain energy density significantly lower than that of the coating layer 160, below the coating layer 160, initial defects on the surface of the second insulating layer 130 may be alleviated from spreading upwardly through repeated high and low temperatures through heat treatment. In that, in the buffer layer 140, tension occurs in a direction opposite to the stress (compression) of the second insulating layer 130 in the lower area facing the second insulating layer 130, and in the upper area facing the coating layer 160, compression may occur in a direction opposite to the tension of the coating layer 160. Accordingly, cracks in the second insulating layer 130 may not extend to the upper coating layer 160 and may be dispersed within the buffer layer 140.

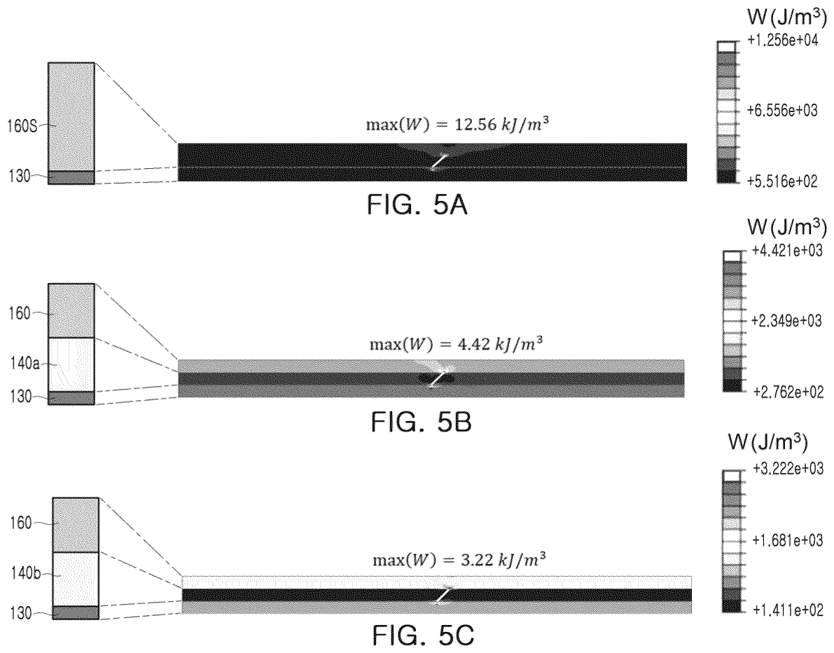

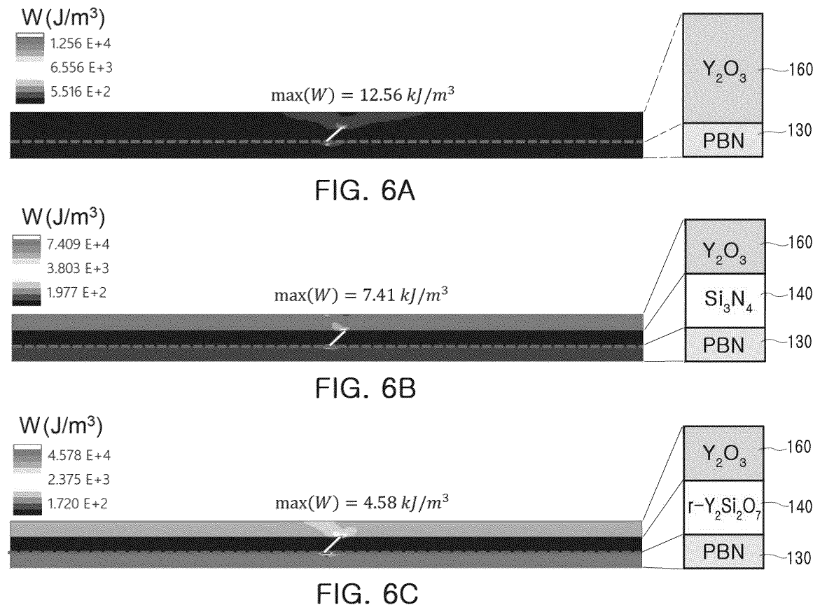

Hereinafter, with reference to FIGS. 5A to 5C and 6A to 6C, simulation results for selecting the optimal material that may form the buffer layer 140 will be described.

Referring to FIGS. 5A to 5C, in various experimental examples in which yttrium oxide (Y₂O₃) was applied as the coating layer 160 and pyrolytic boron oxide (pBN) was applied as the second insulating layer 130, the effect was verified by assuming a material with a certain stiffness and a certain thermal expansion compression (CTE). The assumed physical properties are as illustrated in [Table 1].

TABLE 1

| | | First | Second | |
|---|---|---|---|---|
| | | Experimental | Experimental | |
| Characteristics | pBN | Example | Example | Y₂O₃ |
| Stiffness (GPa) | 36.5 | 60 | 120 | 120 |
| Thermal conductivity | 0.25 | 0.034 | 0.034 | 0.034 |
| (W/m · K) | | | | |
| CTE (10 − 6/K) | 2.7 | 8 | 4 | 8 |

FIG. 5A illustrates a structure in which only the coating layer 160 containing yttrium oxide (Y₂O₃) is disposed directly on the second insulating layer 130, which is a comparative example. FIG. 5B is a first experimental example, illustrating a structure in which a buffer layer 140a formed of a material whose stiffness has been reduced by about ½ with respect to yttrium oxide (Y₂O₃) and a coating layer 160 containing yttrium oxide (Y₂O₃) are sequentially stacked on the second insulating layer 130. FIG. 5C is a second experimental example, illustrating a structure, in which a buffer layer 140b formed of a material of which only thermal expansion coefficient has been reduced to about ½ with respect to yttrium oxide (Y₂O₃), and a coating layer 160 containing yttrium oxide (Y₂O₃), are sequentially stacked. FIGS. 5A to 5C are graphs illustrating the strain energy density (W) of the structures.

In each stacked structure of FIGS. 5A to 5C, it was set that a crack (for example, 0.05 mm in length and 0.05 mm in height, and was set as a crack in the same direction in all experimental and comparative examples) occurred at the interface between the second insulating layer 130 and the upper layer. The strain energy density (W) in the laminated structures of FIGS. 5A to 5C has the highest range in the laminated structures of FIG. 5A, and in detail, may be seen that the maximum strain energy density (max (W)) is found in the area where the crack occurred and the area around the crack. In addition, as illustrated in FIGS. 5B and 5C, both the first and second experimental examples in which the stiffness was reduced to ½ or the thermal expansion coefficient was reduced to ½ had a range of strain energy density (W) that was smaller than that of the comparative example. Therefore, it may be confirmed that the stiffness and thermal expansion coefficient of the buffer layer 140 affect the strain energy density (W). In detail, for the maximum strain energy density (max (W)) at the crack tip, which determines crack propagation, being 12.56 KJ/m³, it was confirmed that they decreased significantly to 4.42 KJ/m³ and 3.22 KJ/m³, respectively in the case of the first and second experimental examples including the buffer layer 140 having lower stiffness and lower thermal expansion coefficient than yttrium oxide (Y₂O₃). Accordingly, a material that satisfies the range of thermal expansion coefficient and stiffness for a strain energy density (W) smaller than that of the coating layer 160 may be applied to the buffer layer 140.

The physical properties of candidate materials applicable to the coating layer 160 and the buffer layer 140 are illustrated in Table 2 below.

TABLE 2

| Substance | | | | | | | | | | |
|---|---|---|---|---|---|---|---|---|---|---|
| Name/ | | | | | | | | | | |
| Physical | | | | | | | | | | |
| Properties | Si₃N₄ | Γ-Y₂Si₂O₇ | AlN | a-SiC | WC | B-SiC | B₂C | ZrC | Al₂O₃ | Y₂O₃ |
| CTE(10⁻⁶/ | 2.9 | 3.9 | 4.3 | 4.7 | 4.9 | 5.1 | 5.5 | 6.6 | 7~8 | 8.0 |
| K) | | | | | | | | | | |
| Stiffness( | 310 | 155 | 330 | 275 | 600 | 430 | 460 | 440 | 295 | 120 |
| GPa) | | | | | | | | | | |
| Coeff. | 2607.1 | 2357.55 | 6101.7 | 6074.75 | 14406 | 11184.3 | 13915 | 19166.4 | 16593.75 | 7680 |

For a specific coefficient (Coeff.) of the coating layer 160, the material applicable to the buffer layer 140 may be defined as a material whose specific coefficient (Coeff.) satisfies ½ or less of the specific coefficient (Coeff.) of the coating layer 160. When applying a material with a small specific coefficient (Coeff.) to the buffer layer 140 so as to satisfy ½ or less of the specific coefficient (Coeff.) of the coating layer 160, the strain energy density (W) proportional to this may have a significantly lower value than the strain energy density (W) of the coating layer 160. Therefore, the maximum strain energy density (max (W)), which is the maximum value among the strain energy densities (W) in the laminated structure, is not greater than the maximum strain energy density (max (W)) of the coating layer 160, and thus, a stable laminated structure may be obtained. A stable laminated structure may mean that cracks in the lower part extend upwardly and are not formed as cracks in the upper coating layer 160, but are dispersed within the buffer layer 140. Therefore, cracks may not occur on the surface of the coating layer 160 forming the outermost surface 100T, thereby reducing damage to the substrate holder 100 and increasing lifespan thereof.

For example, when the coating layer 160 includes yttrium oxide (Y₂O₃), silicon nitride (Si₃N₄) and yttrium silicate (Γ-Y₂Si₂O₇), which are smaller than ½ of the specific coefficient (Coeff.) of yttrium oxide (Y₂O₃), may be selected as suitable materials for the buffer layer 140. In addition, when the coating layer 160 is tungsten carbide (WC), silicon nitride (Si₃N₄), yttrium silicate (Γ-Y₂Si₂O₇), aluminum nitride (AlN) α-silicon carbide (a-SiC), yttrium oxide (Y₂O₃) may be selected as a suitable material for the buffer layer 140.

As an example, in FIGS. 6A to 6C, the strain energy density (W) for each laminated structure is illustrated. Regarding yttrium oxide (Y₂O₃) suitable as the coating layer 160, FIG. 6B, FIG. 6C respectively illustrate, through simulation, the strain energy density (W) of a layered structure respectively including silicon nitride (Si₃N₄) and yttrium silicate (Γ-Y₂Si₂O₇) as the buffer layer 140, as a material with an appropriate specific coefficient (Coeff.) value.

FIG. 6A illustrates a structure in which only the coating layer 160 containing yttrium oxide (Y₂O₃) is disposed directly on the second insulating layer 130, which is a comparative example. FIG. 6B is a first experimental example, illustrating a structure in which a buffer layer 140 of silicon nitride (Si₃N₄) and a coating layer 160 containing yttrium oxide (Y₂O₃) are sequentially stacked on the second insulating layer 130. FIG. 6C is a second experimental example, illustrating a structure in which a buffer layer 140 of yttrium silicate (Γ-Y₂Si₂O₇) and a coating layer 160 containing yttrium oxide (Y₂O₃) are sequentially stacked on the second insulating layer 130. FIGS. 6A to 6C are graphs illustrating the strain energy density (W).

In FIG. 6A, the maximum strain energy density (max (W)) meets 12.56 KJ/m³, in FIG. 6B, the maximum strain energy density (max (W)) meets 7.41 KJ/m³, and in FIG. 6C, the maximum strain energy density (max (W)) may meet 4.58 KJ/m³. In this manner, if the specific coefficient (Coeff.) satisfies ½ or less of the coating layer 160, a stable structure is possible because the maximum strain energy density (max (W)) does not exceed the maximum strain energy density (max (W)) of the coating layer 160.

In this manner, the effects described above may be sufficiently obtained by selecting a material whose specific coefficient (Coeff.) is ½ or less of the specific coefficient (Coeff.) of the coating layer 160 and applying the material to the buffer layer 140.

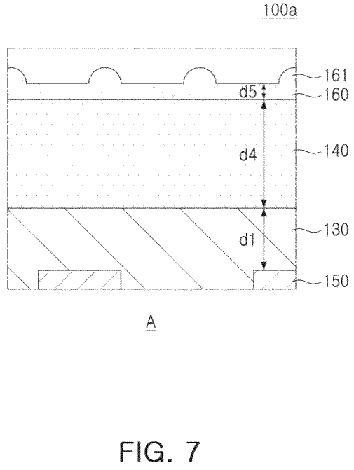

Below, example embodiments are described with reference to FIGS. 7 to 10.

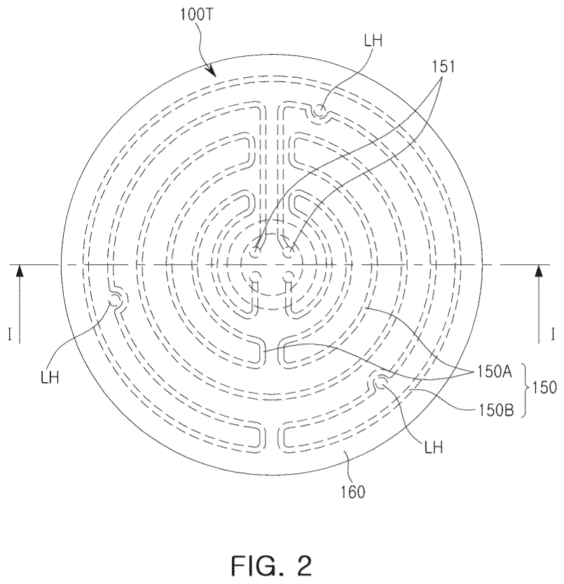

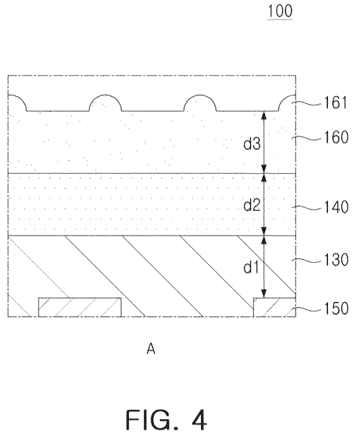

The substrate holder 100a of FIG. 7 is the same as the substrate holder 100 of FIGS. 1 to 4 except that the buffer layer 140 and the coating layer 160 have different thicknesses from those of FIGS. 1 to 4. In the substrate holder 100a of FIG. 7, the second insulating layer 130 may include a first thickness d1. The first thickness d1 may be 100 μm to 300 μm. The first thickness d1 may be defined as the vertical distance from the top surface of the upper electrode layer 150 to the top surface of the second insulating layer 130.

The buffer layer 140 on the second insulating layer 130 may have a fourth thickness d4, and the coating layer 160 may have a fifth thickness d5 on the buffer layer 140. The fourth thickness d4 of the buffer layer 140 may be greater than the fifth thickness d5 of the coating layer 160. For example, the fourth thickness d4 may be 5 to 10 times the fifth thickness d5. For example, when the coating layer 160 has a thickness of 10 μm, the buffer layer 140 may be arranged to have a thickness of 100 μm. The coating layer 160 disposed in this way may be formed to a minimum thickness to form the upper protruding pattern 161, but is not limited thereto.

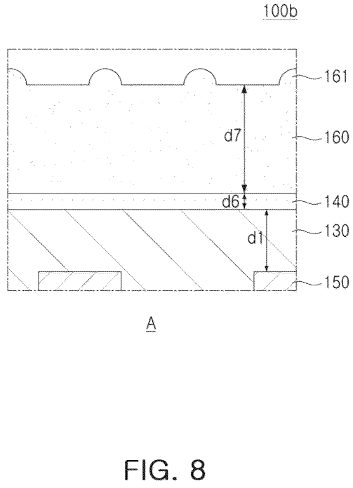

The substrate holder 100b of FIG. 8 is the same as the substrate holder 100 of FIGS. 1 to 4 except that the buffer layer 140 and the coating layer 160 have different thicknesses from those of FIGS. 1 to 4. In the substrate holder 100b of FIG. 7, the second insulating layer 130 may include a first thickness d1. The first thickness d1 may be 100 μm to 300 μm. The first thickness d1 may be defined as the vertical distance from the top surface of the upper electrode layer 150 to the top surface of the second insulating layer 130.

The buffer layer 140 on the second insulating layer 130 may have a sixth thickness d6, and the coating layer 160 may have a seventh thickness d7 on the buffer layer 140. The sixth thickness d6 of the buffer layer 140 may be smaller than the seventh thickness d7 of the coating layer 160. For example, the seventh thickness d7 may be 5 to 10 times the sixth thickness d6. For example, when the buffer layer 140 has a thickness of 10 μm, the coating layer 160 may be arranged to have a thickness of 100 μm. The coating layer 160 arranged in this way forms a protruding pattern 161 at the top and is formed with a sufficiently thick thickness to strengthen the stiffness of the outermost surface 100T.

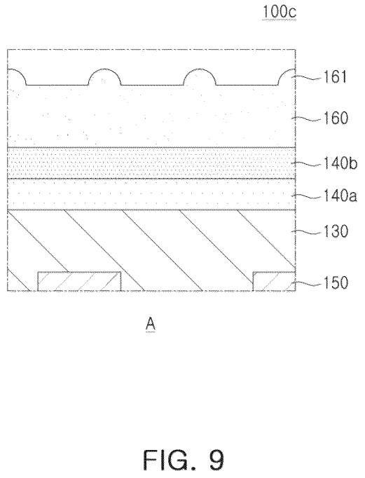

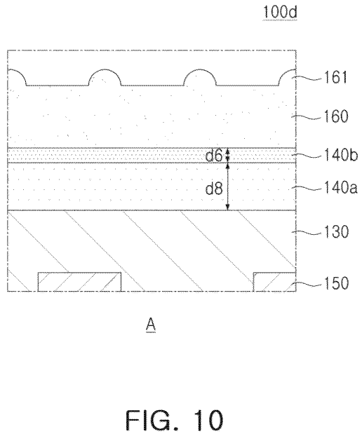

The substrate holder 100c of FIG. 9 is the same as the substrate holder 100 of FIGS. 1 to 4 except that the buffer layer 140 has a multilayer structure. In the substrate holder 100c of FIG. 9, the second insulating layer 130 may include a first thickness d1. The first thickness d1 may be 100 μm to 300 μm. The first thickness d1 may be defined as the vertical distance from the top surface of the upper electrode layer 150 to the top surface of the second insulating layer 130. A first buffer layer 140a may be disposed on the second insulating layer 130, and a second buffer layer 140b may be disposed on the first buffer layer 140a.

The first buffer layer 140a and the second buffer layer 140b may include different materials, For example, when the coating layer 160 includes yttrium oxide (Y₂O₃), the first buffer layer 140 includes silicon nitride (Si₃N₄), and the second buffer layer 140b may include yttrium silicate (Γ-Y₂Si₂O₇). On the other hand, in contrast, the first buffer layer 140a may include yttrium silicate (Γ-Y₂Si₂O₇), and the second buffer layer 140b may include silicon nitride (Si₃N₄). The first buffer layer 140a and the second buffer layer 140b may have the same thickness, and the sum of the thicknesses of the first buffer layer 140a and the second buffer layer 140b may satisfy a range similar to the thickness of the coating layer 160. The coating layer 160 on the second buffer layer 140b may be formed to form an upper protruding pattern 161, but is not limited thereto.

The substrate holder 100d of FIG. 10 is the same as the substrate holder 100 of FIG. 9 except that when the buffer layer 140 has a multilayer structure, the plurality of buffer layers 140 have different thicknesses. In the substrate holder 100d of FIG. 10, the second insulating layer 130 may include a first thickness d1. The first thickness d1 may be 100 μm to 300 μm. The first thickness d1 may be defined as the vertical distance from the top surface of the upper electrode layer 150 to the top surface of the second insulating layer 130. A first buffer layer 140a may be disposed on the second insulating layer 130, and a second buffer layer 140b may be disposed on the first buffer layer 140a.

The first buffer layer 140a and the second buffer layer 140b may include different materials, and for example, when the coating layer 160 includes yttrium oxide (Y₂O₃), the first buffer layer 140a includes silicon nitride (Si₃N₄), and the second buffer layer 140b may include yttrium silicate (Γ-Y₂Si₂O₇). On the other hand, in contrast, the first buffer layer 140a may include yttrium silicate (Γ-Y₂Si₂O₇), and the second buffer layer 140b may include silicon nitride (Si₃N₄). The first buffer layer 140a may have a first buffer thickness d8, and the second buffer layer 140 may have a second buffer thickness d9. The first buffer thickness d8 and the second buffer thickness d9 may be different from each other, and the first buffer thickness d8 may have a larger value, but is not limited thereto. For example, the second buffer thickness d9 may have a larger value, and one buffer thickness d8 and d9 may satisfy a range of 5 to 10 times that of the other buffer thickness d8 and d9.

At this time, the first buffer layer 140a and the second buffer layer 140b may have a multiple layer structure, and for example, may have a multi-layer structure in which the first buffer layer 140a and the second buffer layer 140b alternate with each other, and the first buffer layer 140a may be implemented with at least 2 to 3 layers, and the second buffer layer 140b may also be implemented with at least 2 to 3 layers, but is not limited thereto. Additionally, it may be set to have different thicknesses depending on each material selected.

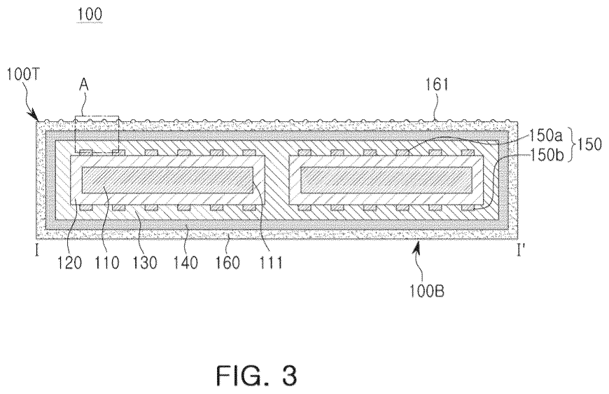

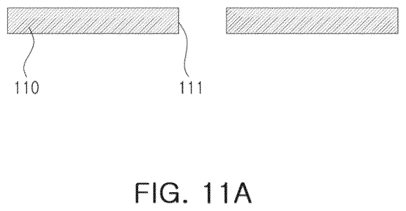

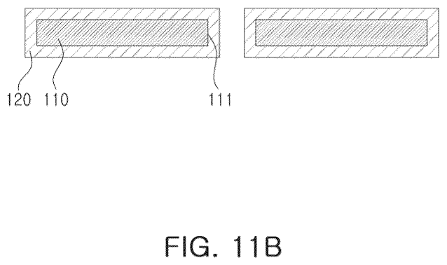

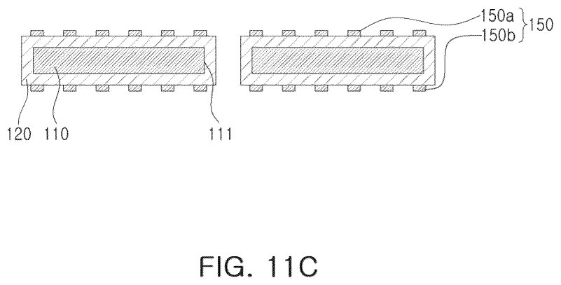

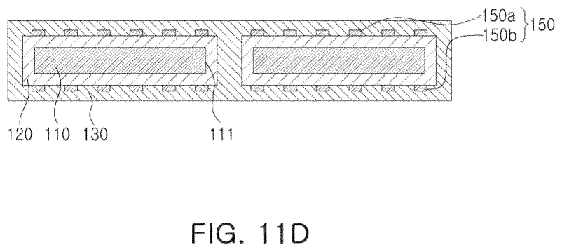

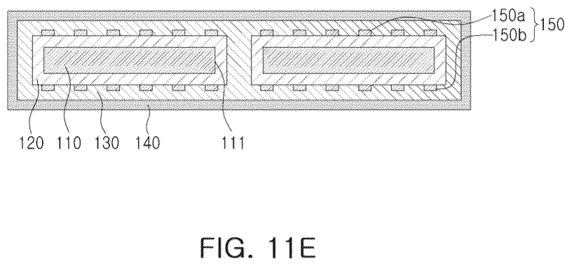

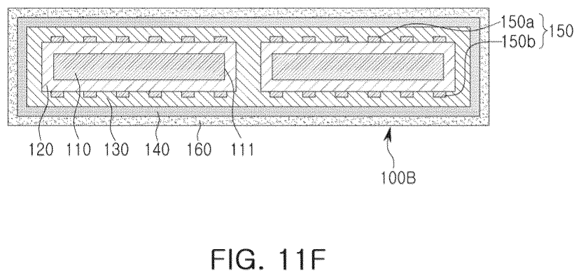

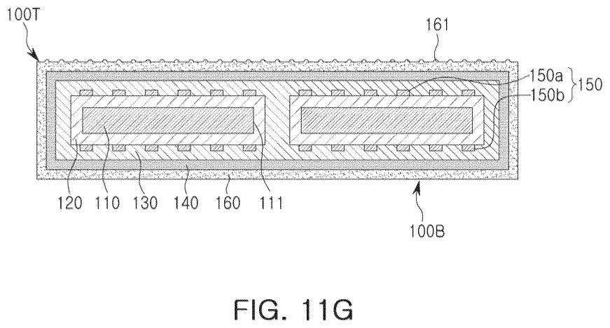

Hereinafter, a process for manufacturing the substrate holder 100 of FIG. 3 will be described with reference to FIGS. 11A to 11G.

First, referring to FIG. 11A, the core body 110 may be molded. The core body 110 may be formed to have an overall shape by initially processing carbon or graphite among carbon composite materials as a base material, smoothing the surface, and forming an opening hole 111 in the central area. The molded core body 110 may have impurities removed through ultrasonic cleaning and drying. Ultrasonic cleaning may be performed within 3 minutes, and then dried at 100° C. or higher for 1 hour or more.

Referring to FIG. 11B, the first insulating layer 120 may be disposed on the core body 110. The first insulating layer 120 may be deposited on the entire core body 110 through chemical vapor deposition (CVD) of pyrolytic boron nitride, which has a thermal expansion rate similar to that of the core body 110.

Boron (B)-related precursors may be coated on the entire core body 110 by applying the CVD method at high temperature, and the deposition thickness may be about 100 to 300 μm. At this time, the mismatch between the lattice constants of graphite and pBN is very small, about 1 to 3%, so that stable crystal growth may be obtained. The first insulating layer 120 is formed by depositing pBN, and the first insulating layer 120 may be formed to cover the core body 110 up to the inside of the opening hole 111. Impurities may be removed through ultrasonic cleaning and drying. Ultrasonic cleaning may be performed within 3 minutes, and then dried at 100° C. or higher for 1 hour or more.

Referring to FIG. 11C, an electrode layer 150 including upper electrodes 150a and lower electrodes 150b may be formed on the upper and lower surfaces of the first insulating layer 120, respectively.

First, the conductive layer 150 may be deposited entirely on the upper and lower surfaces of the first insulating layer 120. The conductive layer 150 may be deposited using pyrolytic graphite (PG) using chemical vapor deposition (CVD) to have a thickness of about 50 μm. Next, the conductive layer 150 may be patterned to have an upper electrode 150a on the upper surface and a lower electrode 150b on the lower surface. Once patterning is completed, it is necessary to check whether the pyrolytic graphite deposited by chemical vapor deposition (CVD) may work well as an electrode, and the dimensions and electrical resistance of the coated electrode may be changed depending on the required resistance. After inspection, impurities may be removed again through ultrasonic cleaning and drying. Ultrasonic cleaning may be performed within 3 minutes, and then dried at 100° C. or higher for 1 hour or more.

Referring to FIG. 11D, the second insulating layer 130 may be formed to cover the upper electrode 150a and the lower electrode 150b. The second insulating layer 130 may be formed of the same pBN as the first insulating layer 120, and pBN may be deposited from the conductive layer 150 to have a thickness of 100 μm to 300 μm using chemical vapor deposition to cover the entire first insulating layer 120 and the upper and lower electrode layers 150. At this time, the opening hole 111 may be completely filled and the second insulating layer 130 may be deposited to have a flat top surface. Impurities may be removed again through ultrasonic cleaning and drying. Ultrasonic cleaning may be performed within 3 minutes, and then dried at 100° C. or higher for 1 hour or more.

Referring to FIG. 11E, the buffer layer 140 may be formed on the second insulating layer 130. The buffer layer 140 may be selected as an optimal material depending on the material forming the coating layer 160 to be laminated later. A material having a specific coefficient (Coeff.) of ½ or less of the specific coefficient (Coeff.) of the material of the coating layer 160 may be selected. For example, when the coating layer 160 includes yttrium oxide (Y₂O₃), yttrium silicate (Γ-Y₂Si₂O₇) may be laminated on the second insulating layer 130 using a chemical vapor deposition method so that the buffer layer 140 includes yttrium silicate (Γ-Y₂Si₂O₇). At this time, it may be deposited to cover the entire top, side, and bottom of the second insulating layer 130. An ultrasonic cleaning and drying process may be further included before and after depositing the buffer layer 140, and the buffer layer 140 may be deposited on the second insulating layer 130 free of cracks and impurities.

Next, referring to FIG. 11F, the coating layer 160 may be formed on the buffer layer 140.

Since the surface of the coating layer 160 becomes the outermost surface 100T of the substrate holder 100, the coating layer 160 may include a material having higher stiffness than the second insulating layer 130, and for example, may include at least one of a lanthanum oxide series, a metal oxide, a metal nitride, and a metal carbide. The coating layer 160 may be chemical vapor deposited to meet a thickness between 1 μm and 1 mm. For example, when the coating layer 160 is formed with yttrium oxide (Y₂O₃), it has higher stiffness than the second insulating layer 130 and has plasma resistance to support the substrate during various heat treatments and plasma treatments in the chamber. The lifespan of the substrate holder 100 may be extended and the replacement period may be delayed. After depositing the coating layer 160, an ultrasonic cleaning and drying process may be further included, and the coating layer 160 may be deposited on the buffer layer 140 free of cracks and impurities.

In FIG. 11G, a protruding pattern 161 may be formed on the surface of the coating layer 160. The protruding pattern 161 may be embossed only on a portion of the surface of the coating layer 160, specifically the upper surface, and the height and diameter of the embossing may vary depending on the overall diameter. The embossing treatment may be performed through wet etching, etc., but is not limited thereto. When the protruding pattern 161 is formed on the surface of the coating layer 160, the substrate holder 100 may be formed by performing an appearance inspection, performing finishing processing, performing a resistance value, dimensional inspection, and alcohol cleaning.

In this manner, by placing the buffer layer 140, which has a strain energy density (W) significantly lower than that of the coating layer 160, below the coating layer 160, initial defects occurring on the surface of the second insulating layer 130 may be alleviated from spreading upwardly through repeated high and low temperatures through heat treatment.

The substrate processing apparatus of this embodiment may be a PECVD device as previously described. For example, referring to FIG. 1, shower head 240 may also function as an upper electrode of a parallel plate electrode.

By disposing a lower electrode (ground electrode) in the second insulating layer 130 of the substrate holder 100 and supplying high frequency power to the shower head 240, a high-frequency electric field is formed between the shower head 240 and the lower electrode, and the process gas supplied from the shower head 240 may be converted into plasma by this high-frequency electric field. In an embodiment, the process chamber 210 may further include a plasma generator that generates plasma from the process gas. For example, the plasma generator may have a capacitive coupled plasma source or an induced coupled plasma source.

In the above-described embodiment, the substrate processing apparatus is illustrated as a PECVD device, but the substrate holder 100 according to the present embodiment may be advantageously employed in other types of substrate processing apparatuses that heat a substrate (for example, a semiconductor wafer) to a high temperature. For example, in addition to the PECVD device, the substrate processing apparatus may also be implemented with a deposition device such as another CVD device or sputtering device, and an etching device such as a plasma etching device.

As set forth above, in some embodiments, stress concentration applied to a coating layer may be reduced by further including a buffer layer to alleviate crack formation between a heating resistance layer and a coating layer. Accordingly, cracks occurring on the surface of the heating resistance layer may extend to the surface along the coating layer, thereby suppressing cracks on the surface of the heater exposed externally. Therefore, the lifespan of the heater may be extended by preventing cracks in the coating layer.

While example embodiments have been illustrated and described above, it will be apparent to those skilled in the art that modifications and variations could be made without departing from the scope of the disclosure as defined by the appended claims.

What is claimed is:

1. A substrate holder comprising:
a core body having a first surface facing a direction in which a substrate is mounted and a second surface opposite to the first surface;
an electrode layer on the first surface and the second surface of the core body;
a ceramic insulating layer covering the electrode layer on the first surface and the second surface of the core body;
a coating layer covering the ceramic insulating layer and forming an outermost surface facing the substrate; and
a buffer layer between the ceramic insulating layer and the coating layer,
wherein the buffer layer comprises a material having a strain energy density lower than a strain energy density of the coating layer.

2. The substrate holder of claim 1, wherein the electrode layer comprises,
an upper electrode layer on the first surface of the core body and configured to provide electrostatic force to the substrate; and
a lower electrode layer on the second surface of the core body and configured to provide heat to the substrate, as a heating resistor.

3. The substrate holder of claim 1, wherein the coating layer comprises a material having stiffness greater than stiffness of the ceramic insulating layer.

4. The substrate holder of claim 3, wherein the buffer layer comprises a material having a strain energy density of a half (½) or less of the strain energy density of the coating layer.

5. The substrate holder of claim 3, wherein the strain energy density of the buffer layer is greater than the strain energy density of the ceramic insulating layer, and
wherein the strain energy density of the buffer layer is lower than the strain energy density of the coating layer.

6. The substrate holder of claim 3, wherein the ceramic insulating layer comprises:
a first insulating layer on the core body and covering the core body; and
a second insulating layer on the electrode layer and the first insulating layer, and
wherein a surface of the second insulating layer is flat.

7. The substrate holder of claim 6, wherein the first insulating layer and the second insulating layer comprise the same material.

8. The substrate holder of claim 6, wherein a thickness of the coating layer is equal to a thickness of the buffer layer.

9. The substrate holder of claim 6, wherein a thickness of the coating layer is less than a thickness of the buffer layer.

10. The substrate holder of claim 6, wherein the buffer layer comprises:
a first buffer layer on the second insulating layer; and
a second buffer layer on the first buffer layer, and
wherein the first buffer layer and the second buffer layer comprise different materials.

11. The substrate holder of claim 10, wherein a thermal expansion coefficient of the first buffer layer is lower than a thermal expansion coefficient of the second buffer layer, and
wherein stiffness of the first buffer layer is higher than stiffness of the second buffer layer.

12. The substrate holder of claim 1, wherein the electrode layer comprises pyrolytic graphite,
wherein the ceramic insulating layer comprises pyrolytic boron nitride, and
wherein the coating layer comprises yttrium oxide.

13. A substrate holder comprising:
a core body having a first surface facing a direction in which a substrate is mounted and a second surface opposite to the first surface;
an electrode layer on the core body, the electrode layer comprising pyrolytic graphite configured to provide heat to the substrate;
a ceramic insulating layer covering the electrode layer, the ceramic insulating layer being located on the first surface and the second surface of the core body, and the ceramic insulating layer comprising pyrolytic boron nitride;
a coating layer covering the ceramic insulating layer, the coating layer being configured to provide an outermost surface facing the substrate, and the coating layer comprising at least one of a lanthanum oxide series, a metal oxide, a metal nitride, and a metal carbide, wherein stiffness of the coating layer is higher than stiffness of the pyrolytic boron nitride; and
a buffer layer between the ceramic insulating layer and the coating layer, the buffer layer comprising at least one of silicon nitride (Si₃N₄), yttrium silicate (Γ-Y₂Si₂O₇), aluminum nitride (AlN), α-silicon carbide (α-SiC), tungsten carbide (WC), β-silicon carbide (β-SiC), boron carbide (B₄C) and zirconium carbide (ZrC).

14. The substrate holder of claim 13, wherein the buffer layer comprises a material having a strain energy density lower than a strain energy density of a material forming the coating layer.

15. The substrate holder of claim 14, wherein the buffer layer comprises a material having a strain energy density of a half (½) or less of the strain energy density of the coating layer.

16. The substrate holder of claim 14, wherein the buffer layer comprises a material having the strain energy density greater than the strain energy density of the pyrolytic boron nitride and lower than the strain energy density of the coating layer.

17. The substrate holder of claim 14, wherein the coating layer comprises yttrium oxide, and
wherein the buffer layer comprises silicon nitride or yttrium silicate.

18. The substrate holder of claim 14, wherein the electrode layer comprises:
an upper electrode layer on the first surface of the core body, the upper electrode layer being configured to provide electrostatic force to the substrate; and
a lower electrode layer on the second surface of the core body, the lower electrode layer being configured to provide heat to the substrate, as a heating resistor.

19. A substrate processing apparatus comprising:
a process chamber having an internal space for processing a substrate;
a first support in the internal space and supporting the substrate; and
a gas supplier configured to supply process gas to the internal space,
wherein the first support comprises:
a core body having a first surface facing a direction in which the substrate is mounted and a second surface opposite to the first surface;
an electrode layer on the first surface and the second surface of the core body;
a ceramic insulating layer covering the electrode layer on the first surface and the second surface of the core body;
a coating layer covering the ceramic insulating layer and being an outermost surface facing the substrate;
a buffer layer between the ceramic insulating layer and the coating layer, the buffer layer comprising a material having a strain energy density lower than a strain energy density of the coating layer;
a plate facing the second surface of the core body;
a second support connected to the plate; and
a power supply line connected to the electrode layer through an inside of the second support.

20. The substrate processing apparatus of claim 19, wherein the electrode layer comprises pyrolytic graphite,
wherein the ceramic insulating layer comprises pyrolytic boron nitride,
wherein the coating layer comprises yttrium oxide, and
wherein the buffer layer comprises silicon nitride or yttrium silicate.
